(19) United States
(12) Patent Application Publication
(10) Pub. No.: US 2019/0179991 A1
(43) Pub. Date: Jun. 13, 2019

(54) METHOD AND SYSTEM FOR TESTING OPTIMIZATION AND MOLDING OPTIMIZATION OF SEMICONDUCTOR DEVICES

(71) Applicants: SHANGHAI IC R&D CENTER CO., LTD., Shanghai (CN); CHENGDU IMAGE DESIGN TECHNOLOGY CO. LTD., Chengdu (CN)

(72) Inventors: Linlin Liu, Shanghai (CN); Ao Guo, Shanghai (CN); Quan Wang, Shanghai (CN); Wei Zhou, Shanghai (CN)

(73) Assignees: SHANGHAI IC R&D CENTER CO., LTD., Shanghai (CN); CHENGDU IMAGE DESIGN TECHNOLOGY CO. LTD., Chengdu (CN)

(21) Appl. No.: 16/311,163

(22) PCT Filed: Jun. 6, 2017
(86) PCT No.: PCT/CN2017/087282

§ 371 Date: Dec. 18, 2018

(30) Foreign Application Priority Data
Sep. 20, 2016 (CN) 201610835616.X

(51) Int. Cl. G06F 17/50; G01R 31/26

(52) U.S. Cl. CPC G06F 17/5036; G06F 2217/78; G01R 31/2601

(57) ABSTRACT

A method and system for testing optimization and molding optimization of semiconductor devices. The testing optimization method is executed based on a test structure for testing the specific non-direct-current parameters, constructing an auxiliary structure of the test structure and testing the non-direct-current parameter, calculating the parallel parasitic resistance and the series parasitic resistance of the test structure based on the parasitic network model and the testing result of the auxiliary structure; performing linear fitting on the parallel parasitic resistance and the series parasitic resistance; and performing a direct-current testing on the test structure to obtain direct-current testing data and correcting the direct-current testing data based on the direct-current equivalent sub-circuit model.

### CROSS-REFERENCE TO RELATED APPLICATION

The application claims the priority benefit of International Patent Application Serial No. PCT/CN2017/087282, filed Jun. 6, 2017, which is related to and claims the priority benefit of China patent application serial No. 201610835616.X filed Sep. 20, 2016. The entirety of each of the above-mentioned patent applications is hereby incorporated by reference herein and made a part of the specification.

### FIELD OF THE INVENTION

The invention relates to the field of testing and modeling for the semiconductor devices, more particularly to a testing optimization method and system for the semiconductor devices, and a modeling optimization method and system for the semiconductor devices.

### BACKGROUND OF THE INVENTION

To modeling of the semiconductor devices, it is necessary to ensure the accurate acquisition of direct-current testing data of the semiconductor devices. The direct-current testing data of the semiconductor devices include the current parameters and voltage parameters and the like.

The direct-current testing data of the semiconductor devices can be obtained in two way: designing a direct-current test structure independently for the semiconductor devices; or directly acquiring the direct-current characteristic of the semiconductor devices on a test structure having other parameters characteristic.

In the testing and modeling processes of the semiconductor devices, the required parameters are not only one type of the direct-current testing data, so that the both approaches have problems.

For the first approach, the testing data for same device (direct-current testing data and other parameter testing data) are carried out on the two test structures respectively, due to the fluctuation influence of the processes, even if the size of the devices is completely the same, it is difficult to guarantee that the direct-current test structure is completely consistent with the devices performance under the test structure having other parameters characteristic. In addition, the connection mode and parasitic factors of the two structures are different, and the methods for eliminating parasitic factors effects are also different, which makes it more difficult to guarantee the identity of data acquisition. The method is used as a basis for modeling semiconductor devices, and when the performance of the semiconductor devices represented by the obtained testing data on the test structures having different parameters characteristic is inconsistent, so that great difficulty is brought to the extraction of the model.

Compared with the first approach, the second approach seems particularly necessary. At least the same structure for different parameter testing is guaranteed in hardware, so that the performance of the semiconductor devices represented by the obtained direct-current testing data and other parameters characteristic are consistent in an ideal state. In fact, the test structure with any parameters inevitably leads to parasitism, and the anti-parasitic measures for the parameters can be designed in a matched mode. However, when the direct-current testing data is obtained through the test structure, the anti-parasitic measures which are not suitable for the parameters are difficult to apply, the obtained performance of the semiconductor devices are still inconsistent, and great difficulty is brought to the extraction of the model, even if the direct-current testing data and other parameters are obtained through the same test structure.

### BRIEF SUMMARY OF THE DISCLOSURE

In order to solve the problem, parasitic elements of a non-direct-current parameter test structure under direct-current bias conditions are extracted, is used for correcting the direct-current testing data of the semiconductor device to optimize the testing and modeling of the semiconductor device.

The invention provides a testing optimization method of a semiconductor device, comprising the following steps, the following steps are executed based on a test structure for testing the specific non-direct-current parameters: constructing an auxiliary structure of the test structure and testing the non-direct-current parameter, calculating the parallel parasitic resistance and the series parasitic resistance of the test structure based on the parasitic network model and the testing result of the auxiliary structure; performing linear fitting on the parallel parasitic resistance and the series parasitic resistance, and a zero-frequency fitting value is obtained to serve as a direct-current parasitic resistance of the test structure, and constructing a direct-current equivalent sub-circuit model of the test structure; performing a direct-current testing on the test structure to obtain direct-current testing data and correcting the direct-current testing data based on the direct-current equivalent sub-circuit model.

In order to achieve the above objects, the present invention further provides a testing optimization system of semiconductor devices to the corresponding testing optimization method, a test structure based on the test specific non-direct-current parameters is adopted, wherein the test structure comprises:

an auxiliary structure testing module, used for testing the non-direct-current parameters of the constructed auxiliary structure of the test structure, and calculating a parallel parasitic resistor and a series parasitic resistor of the test structure based on the parasitic network model and the test result of the auxiliary structure;

the direct-current equivalent sub circuit construction module used for performing linear fitting on the parallel parasitic resistance and the series parasitic resistance, and obtaining a zero-frequency fitting value to serve as a direct-current parasitic resistance of the test structure, and constructing a direct-current equivalent sub-circuit model of the test structure;

the direct-current testing module, used for conducting the direct-current testing on the test structure to obtain direct-current testing data, and correcting the direct-current testing data based on the direct-current equivalent sub-circuit model.

In order to achieve the above objects, the present invention further provides a modeling optimization method of the semiconductor devices, the modeling optimization method comprises the following steps: performing any one of the methods described above on a test structure for testing specific non-direct-current parameters to obtain modeling data; and modeling; wherein the modeling data at least comprise direct-current testing data and testing data of the non-direct-current parameters tested by the test structure.

In order to achieve the above objects, the present invention further provides a modeling optimization system of the semiconductor device, and the modeling optimization system comprises: a modeling data acquisition unit, used for testing specific non-direct-current parameters tested by the test structure, obtaining modeling data from a testing optimization system of the semiconductor devices to the corresponding modeling optimization method described above; a modeling unit used for modeling; wherein the modeling data at least comprise direct-current testing data and testing data of the non-direct-current parameters tested by the test structure.

According to the technical scheme, the test structure of the non-direct-current parameters is directly used, and the influence of the parasitic element of the test structure on the direct-current testing data is eliminated, so that the semiconductor devices represented by the direct-current testing data and the corresponding parameter testing data tend to be consistent, the evaluation of the characteristics of the semiconductor devices are more accurate, and the reliable data is provided for modeling.

A series of simplified forms of concepts are introduced in the summary section of the invention, which will be described in further detail in the detailed description. This summary is not intended to limit key features and essential technical features of the claimed technical solutions, so that the protection scope of the technical scheme required to be protected is not meant to be determined.

The advantages and features of the present invention will be described in detail in conjunction with the accompanying drawings.

### BRIEF DESCRIPTION OF THE DRAWINGS

FIG. 1 shows a basic flow diagram of a testing optimization method of a semiconductor device of the present invention

FIG. 2 illustrates a schematic diagram of a DUT test structure according to a preferred embodiment of the present invention

FIG. 3 illustrates a parasitic network model of a DUT test structure according to a preferred embodiment of the present invention

FIG. 4 illustrates an open circuit auxiliary structure of a test structure according to a preferred embodiment of the present invention

FIG. 5 illustrates a short circuit auxiliary structure of a test structure according to a preferred embodiment of the present invention

FIG. 6 illustrates a parasitic network model of the open circuit auxiliary structure shown in FIG. 4

FIG. 7 illustrates a parasitic network model of the short circuit auxiliary structure shown in FIG. 5 FIG. 8 illustrates a direct-current equivalent sub-circuit model of a test structure according to a preferred embodiment of the present invention

FIG. 9A illustrates an IdVd data curve diagram before and after correction FIG. 9B shows a gate voltage offset Vgs corresponding to five IdVd data curves before and after correction

FIG. 10a illustrates an IdVg data curve diagram before and after correction

FIG. 10b shows a gate voltage offset VDS corresponding to five IdVg data curves before and after correction

FIG. 11a shows a curve diagram of S22 component in the S parameter, wherein the text on an NMOS device under different direct-current bias conditions

FIG. 11b illustrates a correction diagram for S parameter under direct-current bias conditions

FIG. 12 shows a testing optimization system and a modeling optimization system of a semiconductor device according to a preferred embodiment of the present invention

### DETAILED DESCRIPTION OF THE EMBODIMENTS

In the following description, numerous specific details are set forth in order to provide a thorough understanding of the present invention. However, it will be apparent to those skilled in the art, the present invention can be practiced without one or more of these details. In other examples, in order to avoid confusion with the present invention, is not described for some technical features well known in the art.

In order to thoroughly understand the present invention, detailed structures or processes will be set forth in the following description. Obviously, the implementation of the present invention is not limited to the specific details of those skilled in the art. A preferred embodiment of the present invention is described in detail below, however, in addition to these detailed descriptions, the present invention may also have other embodiments.

In the present invention, a testing optimization scheme and a modeling optimization scheme of a semiconductor device are disclosed. It will be understood by those skilled in the art that the applicable object of the present invention is a high-frequency semiconductor device having the problem indicated in the background art, such as a radio frequency (RF) device, a microwave device and the like. In addition, the main process of the semiconductor device should be an MOS (metal oxide semiconductor) process in a predictable period, however it does not imply that the technical scheme of the invention is only suitable for the MOS semiconductor device but is suitable for the equivalent substitution of other processes.

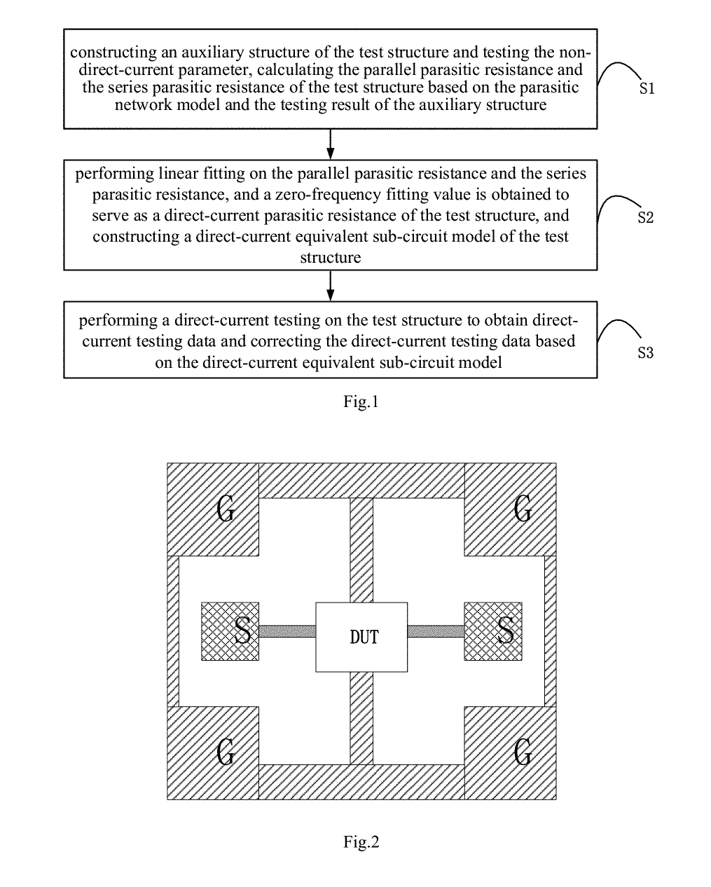

The invention provides a testing optimization method of a semiconductor device and the testing optimization method is based on a test structure for testing specific non-direct-current parameters of a semiconductor device, the direct-current testing and optimization are directly carried out on the direct-current testing device, and the basic flow diagram of the testing optimization method is shown in the FIG. 1.

Those skilled in the art will appreciate that the specific non-direct-current parameters described herein, which is specified or selected by technicians according to actual conditions, and the parameters different from the parameters of the direct-current testing data and is the same as the parameters needed for the modeling of the semiconductor device, for example, scattering parameters (S parameters).

Selection of the S parameters meets the requirements of the invention, and specifically, the S parameter is representative of high frequency performance of the semiconductor device. The current S parameter test structure can bring great parasitism elements, so that the S parameter directly obtained by testing the semiconductor devices cannot accurately represent the performance of the semiconductor devices. Therefore, technicians can further design the de-embedding structure to define the de-embedding plane of the semiconductor devices, namely to define intrinsic devices and parasitic elements, the parasitic elements brought by the S parameter test structure in a high-frequency working state are removed, so that the S parameter data is obtained accurately.

Meanwhile, please note that the parasitic resistance problem introduced in the direct-current state of the S parameter test structure is also not negligible. The invention relates to a semiconductor device with large interdigital and large drain-electrode current, and the introduced parasitic resistance can cause influence on the transconductance of the device, the evaluation of the source/drain resistance and the like. Meanwhile, the design of the connecting line of the S parameter test structure is relatively free, the influence of the parasitic resistance can be further increased under the condition that the design is not optimized.

However, in the prior art, only the influence of the parasitic elements in a high-frequency state is noted, and the processing of the parasitic influence is eliminated through the de-embedding plane. And the influence of parasitic elements is not taken into consideration in the testing process of the direct-current characteristics of the semiconductor devices, so that the performance of the semiconductor devices characterized by the direct-current testing data is inconsistent with the actual performance of the intrinsic devices. Therefore, when the direct-current bias conditions are directly applied to the S parameter test structure, the problems in the background art are certainly solved.

Further, the selection of the S parameter test structure is a better choice of the present invention because the S parameter is a network parameter based on the relationship between incident wave and reflected wave, which facilitates the establishment of parasitic network model.

FIG. 2 shows the schematic diagram of a semiconductor device as DUT in GSGpad (ground-signal-ground welding pad), the GSGpad can be used as a S parameter test structure.

In the parameter testing process of the semiconductor devices as described in the background section, the parasitic elements can be introduced into the test structure, and targeted de-parasitic measures can be carried out. According to the method, an auxiliary structure is designed based on an existing de-parasitic measure, the auxiliary structure is constructed, and a series parasitic factor and a parallel parasitic factor are concerned, in order to prepare the basic data for obtaining the parasitic resistance related to direct-current characteristics.

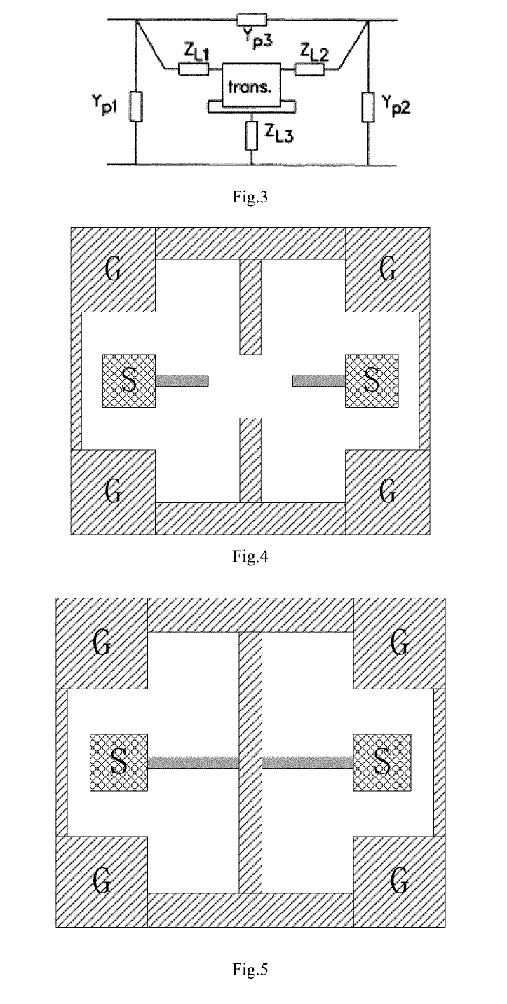

FIG. 3 shows a parasitic network model of the DUT test structure as shown in FIG. 2

Yₚ₁, Yₚ₂, and Yₚ₃ are parallel parasitic elements introduced by the test structure, and Zₗ₁, Zₗ₂ and Zₗ₃ are series parasitic elements introduced by the test structure, and an intrinsic device is in the middle.

The embodiments of the present invention are described in detail with reference to the accompanying drawings.

First, constructing an auxiliary structure of a selected test structure, and testing the non-direct-current parameters selected; and calculating the parallel parasitic resistance and the series parasitic resistance of the test structure based on the parasitic network model and the test result of the auxiliary structure, wherein the step S1 is used for identifying.

Specifically, in order to achieve the calculation of the parallel parasitic resistance and the series parasitic resistance, the auxiliary structure of the test structure needs to be constructed firstly.

As a preferred embodiment, the auxiliary structure can be constructed to be an open circuit auxiliary structure or a short circuit auxiliary structure. Taking the DUT under the GSGPAD as an example, the open circuit auxiliary structure of the DUT is shown in FIG. 4, wherein the short circuit auxiliary structure is as shown in FIG. 5.

Based on the open circuit auxiliary structure and the short circuit auxiliary structure, the step of calculating the parallel parasitic resistance and the series parasitic resistance of the test structure comprises the following steps: testing the non-direct-current parameters of the open circuit auxiliary structure; calculating the parallel parasitic resistance based on the parasitic network model and the test result of the open circuit auxiliary structure; performing the non-direct-current parameter test on the short circuit auxiliary structure, calculating the series parasitic resistance based on the parasitic network model and the test result of the short circuit auxiliary structure.

It should be appreciated that the open-short circuit auxiliary structure is only an auxiliary structure example selected by the embodiment of the present embodiment, the technical personnel in the field can completely manufacture other auxiliary structures of the test structure according to needs to conduct the calculation of the parallel parasitic resistance and the series parasitic resistance of the test structure, for example, a straight-through-reflection-transmission line (TRL) auxiliary structure, an open-thru auxiliary structure, a thru-short circuit an auxiliary structure, an open-short-through-left-right auxiliary structure and the like can be constructed.

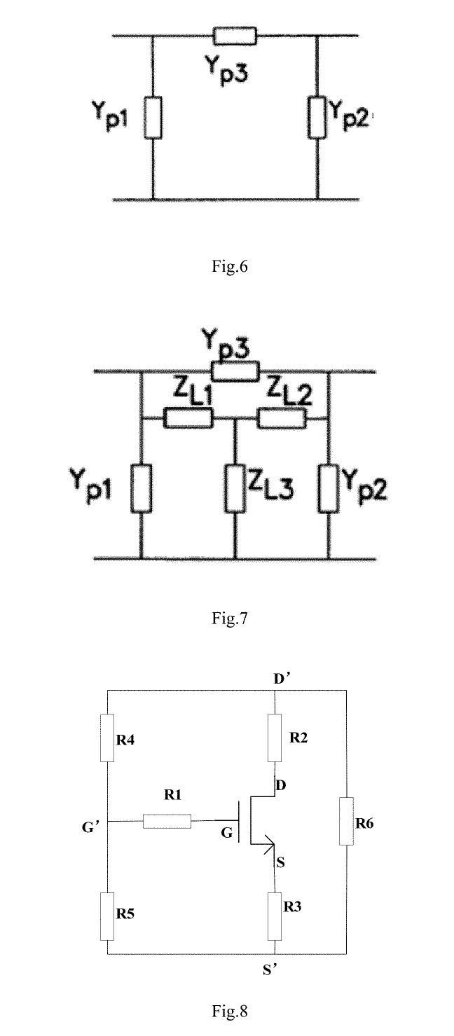

As a specific embodiment, FIG. 6 shows a parasitic network model of the open circuit auxiliary structure shown in FIG. 4, the parasitic network model is a three-element Pi type network, and the steps of calculating the parallel parasitic resistance are as follows: performing corresponding non-direct-current parameter testing on the open circuit auxiliary structure, and calculating the admittance of each element in the Pi type network based on the test result and taking the reciprocal of the real part of each element admittance as the parallel parasitic resistance.

As a specific embodiment, FIG. 7 shows a parasitic network model of the short circuit auxiliary structure shown in FIG. 5, the parasitic network model is in parallel connection with a T-type network of a three-element Pi type network and a three-element T-type network, the steps of calculating the series parasitic resistance are as follows: performing the non-direct-current parameter testing on the short circuit auxiliary structure, calculating the impedance of each element in the T-shaped network based on the test result, and taking the real part of each element impedance as the series parasitic resistance; wherein the Pi type network is determined by a parasitic network model of the open circuit auxiliary structure.

The steps of parallel and series parasitic resistance are determined in the step identified by S1, then a next step is carried out, the parallel parasitic resistance and series parasitic resistance were fitted linearly, and the zero-frequency fitting value was obtained as the direct-current parasitic resistance of the test structure, and the direct-current equivalent sub-circuit model of the test structure was constructed, which was identified as S2.

It should be understood by those skilled in the art that in the processing process of step S1, two sets of tests are carried out on the non-direct-current parameters, therefore the input and output data are frequency-related data. Further, the parasitic network model of FIG. 6 and FIG. 7 is a simplified and ideal network model, the situation in practice is more complicated. In fact, the series parasitic resistance and the parallel parasitic resistance obtained in the step S1 are the variable quantities along with the frequency, rather than a constant, the requirement of direct-current parasitic resistance is not met. Therefore, a linear fitting is carried out, and a zero-frequency fitting value is obtained to serve as a direct-current parasitic resistance of the test structure to solve the problem. As a preferred embodiment, the series-parallel parasitic resistance data of the low-frequency section can be subjected to linear fitting, and the resistance obtained by pushing the extrapolation to 0 hz is used as a series parasitic resistance and parallel parasitic resistance in a direct-current working state.

Next, a direct-current equivalent sub-circuit model of a test structure needs to be constructed. As a preferred embodiment, Mimicking the semiconductor device as a field-effect transistor, wherein the series-connection parasitic resistor comprises R1, R2 and R3, and the parallel parasitic resistor comprises R4, R5 and R6; the gate electrode, the drain electrode and the drain electrode of the field-effect transistor are respectively connected with R1, R2 and R3 in series; and a gate source electrode of the field-effect transistor, and R4, R5 and R6 are respectively connected between the gate electrode and the drain electrode of the field-effect transistor, the gate electrode and the source electrode of the field-effect transistor, and the drain electrode and the source electrode of the field-effect transistor, as shown in FIG. 8.

Next, a direct-current test is performed on the test structure to obtain direct-current testing data, as identified in S3, and correcting direct-current testing data based on the direct-current equivalent sub circuit model.

The direct-current test carried out on the test structure in the step S3 can be realized by directly applying direct-current bias.

Wherein the direct-current testing data, for example, is an IV curve of a semiconductor device.

It should be noted that although the identifier of the step is S3, it is not meant that the step S3 are performed after S1/S2 in the step S1/S2. For example, for performing a direct-current test on the test structure to obtain direct-current testing data, the auxiliary structure can be tested before or after the test of the auxiliary structure in the step S1, without affecting the implementation and technical effects of the technical scheme of the present invention.

It should be understood by those skilled in the art that the respect of the invention mainly focuses on the optimization of the direct-current testing data and does not affect the corresponding non-direct-current parameters test of the test structure according to its original design intention, nor does it affect the normal test of other test structures. In other words, the test structure used for conducting the direct-current test still can be used to test the corresponding non-direct-current parameters, and the other test structures still may carry out respective testing. In the step S3, the step of performing direct-current test on the test structure to obtain direct-current testing data can be carried out before or after the test of each non-direct-current parameter, without affecting the implementation and technical effects of the technical scheme of the present invention.

As a preferred embodiment, the test structure is used in the process of carrying out corresponding non-direct-current parameter testing, the test can be carried out under the condition that the direct-current bias condition is applied, so that the obtained testing data of the non-direct-current parameter can be correlated with the direct-current performance of the semiconductor device, and there exist errors. Therefore, a better technical effect can be obtained if the correction is achieved. According to the preferred embodiment, the direct-current bias condition of the selected test structure can be optimized, a direct-current equivalent sub circuit model is used for correcting a direct-current bias condition applied to the test structure to test a corresponding non-direct-current parameter.

The direct-current bias condition is a direct-current bias condition corresponding to the obtained S parameter, wherein the S parameter is a de-embedded S parameter, and the specific de-embedding method is not within the scope of the present invention.

The testing optimization method of the semiconductor devices provided by the present invention is described. It will be understood by those skilled in the art that the direct-current data testing according to the present invention is directly carried out by means of a test structure of non-direct-current parameters, and a new structure does not need to be added to remove the parasitic influence of the test structure, and the direct-current characteristic of the semiconductor device is corrected, so that the semiconductor devices represented by the direct-current testing data and the corresponding parameter testing data tend to be consistent, the evaluation of the characteristics of the semiconductor device is more accurate, and reliable data is provided for the modeling of the semiconductor device.

In order to help those skilled in the art more clearly understand the technical solutions of the present invention, the specific embodiment and the specific operation processing are further described below. In the embodiment, an NMOS device is used as a DUT, the width w is equal to 5 um, the length 1 is equal to 0.04 um, and the interdigital NF is equal to 16.

(1) Selecting test structure type. In this embodiment, a preferred S parameter test structure is adopted. The semiconductor device acquires relevant performance of the intrinsic device by testing S parameters and by means of de-embedding, and the intrinsic device part and the parasitic part of the device can be distinguished in the process. By means of the test structure, the direct-current performance of the intrinsic device is obtained through the following operation, namely removing the influence of the parasitic element caused by the S parameter test structure.

(2) Selecting specific test structure. In this embodiment, the GSGpad structure is adopted as a specific implementation structure of the S parameter test. In this case, the source electrode and the bulk of the NMOS device is shorted to a ground pad; the gate electrode and the drain electrode of the NMOS device are respectively connected to two Signal pads of the GSGpad.

After the test structure is determined, the parasitic network model of the test structure can be obtained, and parasitic factors introduced by the test structure can be extracted. In the case of the S parameter test structure is adopted, a de-embedding plane is constructed. In this embodiment, the de-embedding plane of gate electrode and drain electrode is selected as M3 (the third layer of metal in CMOS process), while the de-embedding of source electrode and bulk end is M1 (the first layer of metal wiring in CMOS process), and the range of the intrinsic device is defined by the de-embedding plane. The specific selection of the layer of metal is flexibly determined by the technical personnel according to the definition of the intrinsic device, M1 and M3 are selected to be only used as an actual example to be described, the technical personnel can take other options according to the needs completely. On expression, the parasitic network model of the embodiment can follow the schematic diagram of FIG. 3, namely, Yₚ₁, Yₚ₂, and Yₚ₃ are parallel parasitic elements introduced by the test structure, Zₗ₁, Zₗ₂ and Zₗ₃ is a series parasitic element introduced by the test structure, and the middle is an intrinsic device.

(3) Constructing an open circuit auxiliary structure and a short circuit auxiliary structure, and carrying out S parameter test on the open circuit auxiliary structure and the short circuit auxiliary structures respectively.

Base on the GSGpad test structure, the open circuit auxiliary structure is used for removing a device to be tested on the basis of a DUT structure: firstly, a de-embedding plane is selected, for example, the position of the de-embedding plane is determined in the DUT structure, removing the device structures in the de-embedding plane to form an open circuit auxiliary structure. Based on the open circuit auxiliary structure, the gate electrode, the drain electrode and the source electrode are added, with the bulk end through a metal wire to form a short circuit auxiliary structure.

(4) Converting S parameter tested by the open circuit auxiliary structure into Y parameter (admittance parameter), and using a parasitic network model as shown in FIG. 6, the admittance values of the parallel parasitic factors Y_{P3}, Yₚ₁ and Yₚ₂ can be obtained on the basis of the Y parameters:

Yₚ₃=−Y₁₂

Yₚ₁=Y₁₁+Y₁₂

Yₚ₂=Y₂₂+Y₁₂

Next, the real parts of the Y_{P3}, Yₚ₁ and Yₚ₂ are obtained respectively, and taking the inverse to serve as the parallel parasitic resistance of the GSGPAD, namely:

Rₚ₃=1/real(Yₚ₃)

Rₚ₁=1/real(Yₚ₁)

Rₚ₂=1/real(Yₚ₂)

(5) Converting S parameters of the short circuit auxiliary structure test into Y parameters, a parasitic network model shown in FIG. 7 is used, and a Pi type network is composed of Yₚ₃, Yₚ₁, Yₚ₂, and a T-shaped network is formed by the Zₗ₁, Zₗ₂, Zₗ₃, and the Pi type network and the T-shaped network formed are connected in parallel, so that the Y parameter of the T-type network is as follows:

Y_{T}=Yₛₕₒᵣₜ−Yₚᵢ=Yₛₕₒᵣₜ−Yₒₚₑₙ

Converting Y parameters of the T-type network into Z parameters (impedance parameter), the Zₗ₁, Zₗ₂, Zₗ₃ can be solved, wherein:

Z_{L1}=Z_{T11}−Z_{T12}

Z_{L2}=Z_{T12}

Z_{L3}=Z_{T22}−Z_{T12}

Respectively solving the real part of the Zₗ₁, Zₗ₂, Zₗ₃ which is used as a series parasitic resistance of the GSGpad:

Rₗ₁=real(Zₗ₁)

Rₗ₂=real(Zₗ₂)

Rₗ₃=real(Zₗ₃)

(6) Constructing a direct-current equivalent sub-circuit model of the test structure, and using the direct-current equivalent sub-circuit model as shown in FIG. 8. Namely, on the basis of the intrinsic device, the gate electrode is connected with the parasitic resistor R1 in series, and the drain electrode is connected with the parasitic resistor R2 in series, the source electrode is connected with the parasitic resistor R3 in series, and the parasitic resistor R4 is connected between the gate electrode and the drain electrode in parallel, a parasitic resistor R5 is connected between the gate electrode and the source electrode in parallel, and a parasitic resistor R6 is connected between the source electrode and the drain electrode in parallel.

The embodiment adopts a method of extrapolating the low frequency band resistance by linear fitting to the zero-frequency point and determining the resistance value. Specifically, the minimum test frequency of the S parameter is 50 Mhz. And the S parameter can be selected between 50 Mhz and 2 GHz. The corresponding resistance points are respectively calculated at a certain interval, and then linear fitting of the frequencies is carried out, and the point corresponding to 0 hz after fitting is read as direct-current parasitic resistances: the value of R₁ in FIG. 7 is the zero-frequency fitting value of Rₗ₁, R₂ is a zero-frequency fitting value of Rₚ₁, and R₃ is a zero-frequency fitting value of Rₗ₃, R₄ is a zero-frequency fitting value of Rₚ₃ and R₅ is a zero-frequency fitting value of Rₚ₁, R₆ is a zero-frequency fitting value of Rₚ₂.

(7) Applying a set of direct-current bias conditions to perform direct-current testing on the S parameter test structure of the NMOS, namely the GSGpad, obtaining the direct-current testing data such as the IV curve of the semiconductor device.

It should be noted that the processing step (7) and the processing step (3) do not meet the order requirements; that is, the processing step (7) can be performed before or after the processing step (3); and the processing step (7) can also be performed before and after the S parameter test and other non-direct-current parameter testing of the DUT are performed.

(8) Solving a node voltage and current equation and correcting direct-current testing data based on a direct-current equivalent sub circuit model.

$$\begin{matrix}{I}_{ds}^{′} = {I}_{ds} - \frac{{V}_{ds}}{{R}_{6} // ( {R}_{4} + {R}_{5} )} \\ = {I}_{ds} - \frac{{V}_{ds} ( {R}_{4} + {R}_{5} + {R}_{6} )}{{R}_{6} ( {R}_{4} + {R}_{5} )}\end{matrix}$$

$$\begin{matrix}{V}_{ds}^{′} = {V}_{ds} - {I}_{ds}^{′} ( {R}_{2} + {R}_{3} ) \\ = {V}_{ds} - {I}_{ds} ( {R}_{2} + {R}_{3} ) - \frac{{V}_{ds} ( {R}_{4} + {R}_{5} + {R}_{6} ) ( {R}_{2} + {R}_{3} )}{{R}_{6} ( {R}_{4} + {R}_{5} )}\end{matrix}$$

$$\begin{matrix}{V}_{gs}^{′} = {V}_{gs} - {I}_{ds}^{′} {R}_{3} \\ = {V}_{gs} - {I}_{ds} {R}_{3} - \frac{{V}_{ds} ( {R}_{4} + {R}_{5} + {R}_{6} ) {R}_{3}}{{R}_{6} ( {R}_{4} + {R}_{5} )}\end{matrix}$$

Wherein: V_{ds}, V_{gs} are applied to a test structure, the voltage of the drain electrode of the semiconductor device and the voltage of the gate electrode relative to the source electrode, and the voltage of the V_{ds}′, V_{gs}′ is the voltage applied to the drain electrode and the gate electrode of the semiconductor device actually after being corrected, I_{ds}′ is a corrected drain current.

According to the calculation result, the IV characteristic curve of the semiconductor device is corrected, in this embodiment, an IdVd curve and an IdVg curve are obtained.

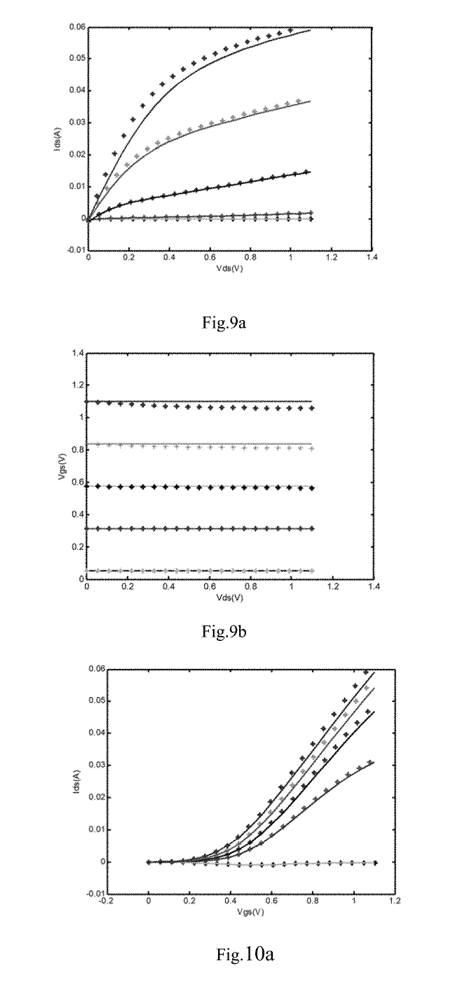

FIG. 9A shows the IdVd data before and after correction, and the line part of the IdVd data is the IdVg data tested before the correction, the symbol part is the corrected data. And the deviation occurs of the IV characteristic due to the parasitic resistance affects the IV characteristic. FIG. 9B shows a gate voltage offset Vgs corresponding to five IdVd data curves before and after correction. And the preset value of the gate voltage offset Vgs for each curve before the correction is as shown in a solid line, the corrected value of the gate voltage offset Vgs is increased along with the Vds and the is gradually deviated from the preset value as shown in the symbol part.

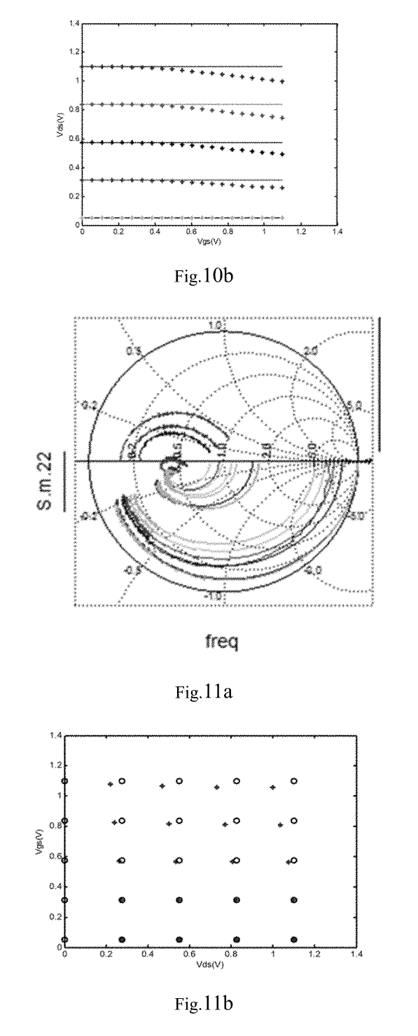

FIG. 10a shows the IdVg data before and after correction, and a line part of the IdVg data is the IdVg data tested before the correction, the symbol part is the corrected data. And the deviation occurs of the IV characteristic due to the parasitic resistance affects the IV characteristic. FIG. 10B shows the gate voltage offset Vds corresponding to the five IdVg data curves before and after correction. And the preset value of the gate voltage offset Vgs for each curve before the correction is as shown in a solid line, the corrected value of the gate voltage offset Vgs is increased along with the Vds and the is gradually deviated from the preset value as shown in the symbol part.

(9) Applying another set of direct-current bias conditions during the S parameter test of the test structure.

For example, the drain-source voltage Vds is scanned 5 points among 0.05 V˜1.1 V with a step length of 0.2625 V, meanwhile, the vgs is also scanned 5 points among 0.05 V˜1.1 V with a step length of 0.2625 V, so that the S parameters of the device under 25 sets of the direct-current bias conditions can be obtained. It is observed that, the direct-current bias condition is used for performing the relevant test of the S parameter instead of performing a direct-current test, so that the sampling number is far lower than that shown in FIG. 9A and FIG. 10A.

And correcting the direct-current bias condition of the direct-current testing data based on the same calculation manner as the direct-current testing data.

As shown in FIG. 11A, to obtain 25 curves obtained by the S22 component in the S parameter under the 25 set bias conditions, each curve corresponds to one set of applied direct-current bias voltage information.

FIG. 11B shows correction for the direct-current bias conditions, and the difference of the direct-current bias voltage corresponding to each curve before and after correction is reflected. Specifically, the circle is 25 sets bias conditions of the S parameters of the device set by the user, and the asterisk is an actual bias condition corresponding to the corrected S parameter of the device, as shown in FIG. 11B, the error is increased along with the increase of the bias voltage.

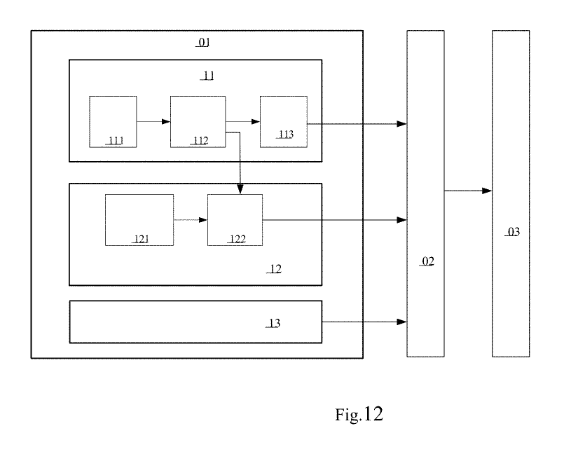

Corresponding to the testing optimization method of the semiconductor device described above, the invention further provides a testing optimization system 01 of the semiconductor device, which is based on the test structure for testing specific non-direct-current parameters, as shown in FIG. 12, the test structure comprises a direct-current testing/optimizing unit 11.

The direct-current testing/optimizing unit 11 comprises:

The auxiliary structure testing module 111 is used for testing the non-direct-current parameters of the constructed auxiliary structure of the test structure and calculating a parallel parasitic resistor and a series parasitic resistor of the test structure 02 based on the parasitic network model and the test result of the auxiliary structure.

Direct-current equivalent sub circuit construction module 112 used for performing linear fitting on the parallel parasitic resistance and the series parasitic resistance and obtaining a zero-frequency fitting value to serve as a direct-current parasitic resistance of the test structure and constructing a direct-current equivalent sub-circuit model of the test structure.

The direct-current testing module 113 is used for conducting the direct-current testing on the test structure to obtain direct-current testing data and correcting the direct-current testing data based on the direct-current equivalent sub-circuit model.

As a preferred embodiment, the system 01 further includes a specific non-direct-current parameter testing/optimization unit 12, wherein the specific non-direct-current parameter testing/optimization unit 12 includes a specific non-direct-current parameter testing module 121 which is used for conducting corresponding non-direct-current parameter testing, and a direct-current bias condition correcting module 122 which is used for correcting the direct-current equivalent sub-circuit model according to the direct-current equivalent sub-circuit model provided by 112, in order to correct the direct-current bias condition applied by the test structure when the non-direct-current parameter is tested.

In addition, those skilled in the art can understand that the system 01 can also include other non-direct-current parameter testing units 13.

The testing optimization method of the semiconductor device has been described in detail in the foregoing, the processing method is also suitable for each corresponding module of the system 01, and therefore, the method is not described in detail in the present invention.

Based on the testing optimization scheme of the semiconductor device, the invention further provides a modeling optimization scheme of the semiconductor device.

The modeling optimization method of the semiconductor device comprises performing any one of the methods described above on a test structure for testing specific non-direct-current parameters to obtain modeling data; and modeling.

The modeling data at least comprises the modeling data at least comprise direct-current testing data and testing data of the non-direct-current parameters tested by the test structure, and the testing data of other non-direct-current parameters can also be included. In addition, the direct-current test and the non-direct-current parameter test are carried out in no order, that is, the direct-current test can occur before and after the test of the non-direct-current parameter. Certainly, the tests with other non-direct-current parameters are carried out in no order.

The modeling optimization system of the semiconductor device is shown in FIG. 12 and comprises: the modeling data obtaining unit 02 is used for obtaining a test structure for testing a specific non-direct-current parameter and obtaining the modeling data from the testing optimization system 01 of the semiconductor device provided by the invention; the modeling unit 03 is used for modeling.

Wherein the modeling data also comprises at least a direct-current testing data and a testing data for testing corresponding non-direct-current parameters of the test structure.

While this invention has been particularly shown and described with references to preferred embodiments thereof, if will be understood by those skilled in the art that various changes in form and details may be made herein without departing from the spirit and scope of the invention as defined by the appended claims.

1. A testing optimization method of a semiconductor device, comprising the following steps, the following steps are executed based on a test structure for testing the specific non-direct-current parameters:
constructing an auxiliary structure of the test structure and testing the non-direct-current parameter, calculating the parallel parasitic resistance and the series parasitic resistance of the test structure based on the parasitic network model and the testing result of the auxiliary structure;
performing linear fitting on the parallel parasitic resistance and the series parasitic resistance, and a zero-frequency fitting value is obtained to serve as a direct-current parasitic resistance of the test structure, and constructing a direct-current equivalent sub-circuit model of the test structure;
performing a direct-current testing on the test structure to obtain direct-current testing data and correcting the direct-current testing data based on the direct-current equivalent sub-circuit model.

2. The method according to claim 1, wherein further comprises correcting a direct-current biasing condition applied to the test structure for testing the non-direct-current parameters based on the direct-current equivalent sub circuit model.

3. The method according to claim 1, wherein the auxiliary structure comprises an open circuit auxiliary structure and a short circuit auxiliary structure; the step of calculating the parallel parasitic resistance and the series parasitic resistance of the test structure comprises the following steps:
testing the non-direct-current parameters of the open circuit auxiliary structure;
calculating the parallel parasitic resistance based on the parasitic network model and the test result of the open circuit auxiliary structure;
performing the non-direct-current parameter test on the short circuit auxiliary structure, calculating the series parasitic resistance based on the parasitic network model and the test result of the short circuit auxiliary structure.

4. The method according to claim 3, wherein, the parasitic network model of the open circuit auxiliary structure is a Pi type network of three elements, the step of calculating the parallel parasitic resistance comprises:
testing the non-direct-current parameters of the open circuit auxiliary structure and calculating the admittance of each element in the Pi type network based on the test result and taking the reciprocal of the real part of each element admittance as the parallel parasitic resistance.

5. The method according to claim 3, wherein the parasitic network model of the short circuit auxiliary structure is in parallel connection with a three-element Pi type network and a three-element T-type network, the step of calculating the series parasitic resistance comprises:
performing the non-direct-current parameter testing on the short circuit auxiliary structure, calculating the impedance of each element in the T-shaped network based on the test result, and taking the real part of each element impedance as the series parasitic resistance; wherein the Pi type network is determined by a parasitic network model of the open circuit auxiliary structure.

6. The method according to claim 1, wherein the constructing direct-current equivalent sub-circuit model for the test structure comprises:
Mimicking the semiconductor device as a field-effect transistor, wherein the series-connection parasitic resistor comprises R1, R2 and R3, and the parallel parasitic resistor comprises R4, R5 and R6; the gate electrode, the drain electrode and the source electrode of the field-effect transistor are respectively connected with R1, R2 and R3 in series; and R4, R5 and R6 are respectively connected between the gate electrode and the drain electrode of the field-effect transistor, the gate electrode and the source electrode of the field-effect transistor, and the drain electrode and the source electrode of the field-effect transistor.

7. The method according to claim 1, wherein the non-direct-current parameter is S parameter.

8. A testing optimization system of semiconductor devices, wherein comprising a test structure based on the test specific non-direct-current parameters, the test structure comprises:
an auxiliary structure testing module, used for testing the non-direct-current parameters of the constructed auxiliary structure of the test structure, and calculating a parallel parasitic resistor and a series parasitic resistor of the test structure based on the parasitic network model and the test result of the auxiliary structure;
the direct-current equivalent sub circuit construction module used for performing linear fitting on the parallel parasitic resistance and the series parasitic resistance, and obtaining a zero-frequency fitting value to serve as a direct-current parasitic resistance of the test structure, and constructing a direct-current equivalent sub-circuit model of the test structure;
the direct-current testing module, used for conducting the direct-current testing on the test structure to obtain direct-current testing data, and correcting the direct-current testing data based on the direct-current equivalent sub-circuit model.

9. A modeling optimization method of a semiconductor device, wherein comprising:
performing the method described in claim 1 on a test structure for testing specific non-direct-current parameters to obtain modeling data; and modeling; wherein the modeling data at least comprise direct-current testing data and testing data of the non-direct-current parameters tested by the test structure.

10. A modeling optimization system of a semiconductor device, wherein comprising:
a modeling data acquisition unit, used for testing specific non-direct-current parameters tested by the test structure, obtaining modeling data from a testing optimization system of the semiconductor device according to claim 8;
a modeling unit used for modeling;
wherein the modeling data at least comprise direct-current testing data and testing data of the non-direct-current parameters tested by the test structure.

11. The method according to claim 2, wherein the non-direct-current parameter is S parameter.

12. The method according to claim 3, wherein the non-direct-current parameter is S parameter.

13. The method according to claim 4, wherein the non-direct-current parameter is S parameter.

14. The method according to claim 5, wherein the non-direct-current parameter is S parameter.

15. A modeling optimization method of a semiconductor device, wherein comprising:
performing the method described in claim 2 on a test structure for testing specific non-direct-current parameters to obtain modeling data; and modeling; wherein the modeling data at least comprise direct-current testing data and testing data of the non-direct-current parameter tested by the test structure.

16. A modeling optimization method of a semiconductor device, wherein comprising:
performing the method described in claim 3 on a test structure for testing specific non-direct-current parameters to obtain modeling data; and modeling; wherein the modeling data at least comprise direct-current testing data and testing data of the non-direct-current parameter tested by the test structure.

17. A modeling optimization method of a semiconductor device, wherein comprising:
performing the method described in claim 4 on a test structure for testing specific non-direct-current parameters to obtain modeling data; and modeling; wherein the modeling data at least comprise direct-current testing data and testing data of the non-direct-current parameter tested by the test structure.

18. A modeling optimization method of a semiconductor device, wherein comprising:
performing the method described in claim 5 on a test structure for testing specific non-direct-current parameters to obtain modeling data; and modeling; wherein the modeling data at least comprise direct-current testing data and testing data of the non-direct-current parameter tested by the test structure.

19. A modeling optimization method of a semiconductor device, wherein comprising:
performing the method described in claim 6 on a test structure for testing specific non-direct-current parameters to obtain modeling data; and modeling; wherein the modeling data at least comprise direct-current testing data and testing data of the non-direct-current parameter tested by the test structure.

20. A modeling optimization method of a semiconductor device, wherein comprising:
performing the method described in claim 7 on a test structure for testing specific non-direct-current parameters to obtain modeling data; and modeling; wherein the modeling data at least comprise direct-current testing data and testing data of the non-direct-current parameter tested by the test structure.
